(19) United States
(12) Patent Application Publication
(10) Pub. No.: US 2025/0324487 A1
(43) Pub. Date: Oct. 16, 2025

(54) JIG DEVICE AND SYSTEM FOR PROVIDING THE DETACHMENT AND INSTALLATION OF THE HEATER UNIT AND A HIGH-PRESSURE ANNEALING DEVICE

(71) Applicant: YEST Co., Ltd., Pyeongtaek-si (KR)

(72) Inventors: Young Joon HAM, Pyeongtaek-si (KR); Jeong Eui KIM, Incheon (KR); Yong Hwan KWON, Yongin-si (KR); Jin Seok LEE, Pyeongtaek-si (KR); Byung Wook HWANG, Anseong-si (KR); Yeon Min MO, Pyeongtaek-si (KR); Eun Chan LEE, Yongin-si (KR); Ryun Hwi KIM, Pyeongtaek-si (KR)

(73) Assignee: YEST Co., Ltd., Pyeongtaek-si (KR)

(21) Appl. No.: 19/176,085

(22) Filed: Apr. 10, 2025

(30) Foreign Application Priority Data
Apr. 11, 2024 (KR) 10-2024-0048587

(51) Int. Cl. H05B 3/02

(52) U.S. Cl. CPC H05B 3/02

(57) ABSTRACT

Disclosed are a jig device for attachment and detachment of a heater unit, a system for attachment and detachment of the heater unit, and a high-pressure annealing device capable of attaching and detaching the heater unit thereto and therefrom. The heater unit is attachable to or detachable from the high-pressure annealing device through upward movement or downward movement of the heater unit from or toward the lower portion of an outer chamber in a state in which the heater unit disposed in the high-pressure annealing device is supported by the jig device.

### CROSS-REFERENCE TO THE RELATED APPLICATION

The present application claims priority to and the benefit of Korean Patent Application No. 10-2024-0048587, filed on Apr. 11, 2024, in the Korean Intellectual Property Office, the entire disclosure of which is incorporated herein by reference.

### BACKGROUND

### 1. Field

The present disclosure relates to a jig device for attachment and detachment of a heater unit, a system for attachment and detachment of the heater unit, and a high-pressure annealing device capable of attaching and detaching the heater unit thereto and therefrom, and more particularly, to a technique through which a heater unit is able to be attached to or detached from a high-pressure annealing device through upward movement or downward movement of the heater unit from or toward the lower portion of an outer chamber in a state in which the heater unit disposed in a high-pressure annealing device is supported by a jig device.

### 2. Description of the Related Art

Semiconductors are manufactured through a number of processes. When an ion implantation process is performed, a wafer interface is damaged due to high collision energy. An annealing process is a process of restoring damage to the wafer surface by changing the temperature of a damaged wafer and supplying process gases to the damaged wafer.

Recently, a high-pressure hydrogen annealing process has been employed to remove semiconductor surface defects using high-pressure hydrogen or deuterium.

Such a high-pressure annealing device adopts a dual chamber structure including an inner chamber configured to perform an annealing process therein in a high-pressure environment and an outer chamber configured to protect the inner chamber by maintaining a pressure corresponding to the high pressure of the inner chamber.

Furthermore, a heater unit is provided to surround the circumference of the inner chamber for heating according to the annealing process of the inner chamber.

In order to perform maintenance work on the high-pressure annealing device, the heater unit needs to be separated from the high-pressure annealing device. In this case, due to the structural limitations of the high-pressure annealing device, the heater unit is separated in such a manner that, after an upper portion of the outer chamber is opened, the heater unit is moved upwards so as to be separated from the high-pressure annealing device through the opened upper portion of the outer chamber.

Additionally, when the heater unit is installed in the high-pressure annealing device, the heater unit is moved downwards through the open upper portion of the outer chamber, and then the heater unit is installed therein.

Meanwhile, in the method of attaching and detaching the heater unit to and from the high-pressure annealing device, the size of the upper portion of the outer chamber needs to be formed corresponding to the size of the heater unit so as to secure a work space, leading to a significant increase in the overall size of the high-pressure annealing device.

In addition, a separate crane device needs to be provided to move the heater unit upwards. Here, when the heater unit is moved upwards, the heater unit may come into contact with the outer chamber or the inner chamber. In this case, the high-pressure annealing device is damaged.

Furthermore, in order to install the heater unit at the exact location between the outer chamber and the inner chamber, it is required to precisely control a crane capable of moving the heater unit upwards and downwards. Accordingly, stability may not be guaranteed, and it may take a long time to complete installation of the heater unit.

### SUMMARY

Therefore, the present disclosure has been made in view of the above problems, and it is an object of the present disclosure to provide a method of attaching or detaching a heater unit to or from a high-pressure annealing device through upward movement or downward movement of the heater unit from or toward the lower portion of an outer chamber in a state in which the heater unit disposed in the high-pressure annealing device is supported by a jig device.

It is another object of the present disclosure to solve various problems related to a heater unit detachment process in which an upper portion of an outer chamber is formed to be open in order to perform maintenance work on a high-pressure annealing device, and then a heater unit is moved upwards so as to be detached from the high-pressure annealing device through the open upper portion of the outer chamber.

It is a still further object of the present disclosure to solve a problem in which, when a method of detaching a heater unit from a high-pressure annealing device through an open upper portion of an outer chamber is performed, a work space corresponding to the size of the heater unit needs to be secured in the upper portion of the outer chamber, leading to a significant increase in the overall size of the high-pressure annealing device.

It is a yet further object of the present disclosure to solve a problem related to the necessity of a separate crane device configured to move a heater unit upwards or downwards, and a problem related to damage to a high-pressure annealing device, occurring when the heater unit comes into contact with an outer chamber or an inner chamber during upward or downward movement of the heater unit.

It is an even further object of the present disclosure to solve a problem in which, since a crane device configured to move a heater unit upwards or downwards needs to be precisely controlled in order to install the heater unit at the exact location between an outer chamber and an inner chamber, stability is not guaranteed, and it takes a long time to complete installation of the heater unit.

The objects of the present disclosure are not limited to the above-mentioned objects, and other technical objects not mentioned herein will be clearly understood by those skilled in the art to which the present disclosure pertains from the detailed description of the embodiments.

In accordance with an aspect of the present disclosure, the above and other objects can be accomplished by the provision of a jig device configured to support attachment and detachment of a heater unit, the jig device including a heater support plate configured to support the heater unit by allowing the heater unit to be mounted on an upper surface thereof, and a jig support plate supported in contact with a door of a high-pressure annealing device or a door support arm of an upward/downward movement device, wherein the heater unit mounted on the upper surface of the heater support plate is moved upwards or downwards by the upward/downward movement device.

The jig device may further include a plurality of mounting guide bars disposed to protrude upwards from the upper surface of the heater support plate and configured to guide mounting of the heater unit on the heater support plate, the mounting guide bars being configured to prevent separation of the heater unit by closely contacting and supporting a side surface of a lower end portion of the heater unit.

The mounting guide bars may include a first mounting guide bar and a second mounting guide bar, and a separation distance between the first mounting guide bar and the second mounting guide bar may be adjusted so as to allow the lower end portion of the heater unit to be inserted into and mounted in a space between the first mounting guide bar and the second mounting guide bar.

The heater support plate may be formed to have a plate shape, and a longitudinal length of the heater support plate may be larger than a diameter of a lower end surface of the heater unit and may be smaller than a diameter of a door insertion space provided in a lower end of an outer chamber.

A width of the heater support plate may be adjusted so as not to cover but to open, among a plurality of heater fastening through-holes configured for a plurality of heater fasteners to be respectively fastened thereinto so as to fixedly mount the heater unit on the outer chamber, the heater fastening through-holes other than the heater fastening through-holes each functioning as an alignment hole.

The heater support plate may be formed to have a disc shape, and a diameter of the heater support plate may be larger than a diameter of the heater unit and may be smaller than a diameter of a door insertion space provided in a lower end of an outer chamber.

The heater support plate may have a plurality of fastening work spaces respectively formed in portions thereof corresponding to a plurality of heater fastening through-holes, the portions being formed to be recessed inwards and open, the heater fastening through-holes being configured for a plurality of heater fasteners to be respectively fastened thereinto, the heater fasteners being configured to fixedly mount the heater unit on the outer chamber.

The jig device may further include an alignment pin formed to protrude upwards from the upper surface of the heater support plate and inserted into an alignment hole provided in the heater unit.

The jig device may further include a plurality of heater unit detection sensors respectively disposed at a plurality of locations of the heater support plate in a state of being spaced apart from each other, each of the heater unit detection sensors being configured to measure a distance between the heater unit and the heater support plate or a degree of pressurization by the heater unit.

The jig device may further include a plurality of jig legs connecting the heater support plate to the jig support plate, and the jig legs may be adjusted in height depending on a size of a required work space.

In accordance with another aspect of the present disclosure, there is provided a system for attachment and detachment of a heater unit, the system including the jig device configured for the heater unit in a high-pressure annealing device to be mounted thereon, and an upward/downward movement device configured to move the jig device upwards or downwards, wherein the heater unit is attached to or detached from the high-pressure annealing device through upward movement or downward movement of the heater unit from or toward a lower portion of an outer chamber of the high-pressure annealing device in a state in which the heater unit is supported by the jig device.

The upward/downward movement device may move a door of the high-pressure annealing device upwards or downwards.

The upward/downward movement device may include a door support arm configured for the door to be mounted thereon, the door support arm being moved upwards or downwards by the upward/downward movement device, and the jig device may be mounted on the door support arm from which the door is removed.

The jig device may include a plurality of heater unit detection sensors respectively disposed at a plurality of locations of a heater support plate in a state of being spaced apart from each other, the heater support plate being configured for the heater unit to be mounted thereon, the heater unit detection sensors each being configured to measure a separation distance between the heater unit and the heater support plate or a degree of pressurization by the heater unit, and the system may further include a controller configured to determine, based on detection signals from the plurality of heater unit detection sensors, an operating state of the jig device or a mounting state of the heater unit.

In accordance with a further aspect of the present disclosure, there is provided a high-pressure annealing device configured to attach or detach a heater unit thereto or therefrom, the high-pressure annealing device including an inner chamber having an inner space formed therein and configured for a heat treatment process on an object to be processed to be performed therein, the inner space being adjusted to a first pressure, an outer chamber having an open lower portion and closed upper and side surface portions formed to be integrated with each other, the outer chamber having an outer space formed to be spaced apart from the inner chamber and configured to accommodate the inner chamber therein, the outer space being adjusted to a second pressure, and a heater unit disposed between the inner chamber and the outer chamber, the heater unit including a heater mounting portion fastened to the outer chamber, the heater mounting portion being selectively fastened to the outer chamber through a heater fastening means such that the heater unit is selectively mounted on the outer chamber and is withdrawn from the open lower portion of the outer chamber.

The heater mounting portion of the heater unit may include a heater flange formed to protrude outwards from a lower end of a heater body, and a heater fastener of the heater fastening means may penetrate an upper surface of the heater flange from a lower surface thereof and may be fastened to the outer chamber in a state in which the upper surface of the heater flange is in contact with a part of the outer chamber, thereby enabling the heater unit to be selectively mounted on the outer chamber.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings.

In the drawings:

FIG. 1 is a perspective view of a high-pressure annealing device to which a system for attachment and detachment of a heater unit according to one embodiment of the present disclosure is applied;

FIG. 2 is a cross-sectional view of the high-pressure annealing device to which the system for attachment and detachment of the heater unit according to one embodiment of the present disclosure is applied;

FIG. 3 is a view showing the system for attachment and detachment of the heater unit according to one embodiment of the present disclosure;

FIG. 4 is a view showing a jig device of the system for attachment and detachment of the heater unit according to one embodiment of the present disclosure;

FIG. 5 is a view showing the size of a heater support plate of the jig device and the size of the heater unit according to one embodiment of the present disclosure;

FIG. 6 is a view showing one embodiment in which the jig device according to the present disclosure is mounted on a door;

FIG. 7 is a view showing another embodiment of the jig device of the system for attachment and detachment of the heater unit according to the present disclosure;

FIG. 8 is a view showing the size of the heater support plate of the jig device and the size of the heater unit according to another embodiment of the present disclosure; and

FIGS. 9 to 11 are views each showing an embodiment of an operation of detaching the heater unit from the high-pressure annealing device through the system for attachment and detachment of the heater unit according to the present disclosure.

### DETAILED DESCRIPTION OF EXEMPLARY EMBODIMENTS

Hereinafter, preferred embodiments of the present disclosure will be described in detail with reference to the accompanying drawings in order to describe the present disclosure, the operational advantages thereof, and the purpose achieved by implementation of the present disclosure.

First, in the present disclosure, the terms used herein are only used to describe specific embodiments and are not intended to limit the present disclosure. In this specification, an expression in a singular form also includes the plural sense, unless clearly specified otherwise in context. Additionally, it should be understood that expressions such as “comprise” and “have” in this specification are intended to designate the presence of indicated features, numbers, steps, operations, components, parts, or combinations thereof, but do not exclude the presence or addition of one or more features, numbers, steps, operations, components, parts, or combinations thereof.

In describing the embodiments disclosed herein, when it is determined that a detailed description of related publicly known techniques may obscure the gist of the embodiments disclosed in this specification, the detailed description thereof will be omitted.

The present disclosure proposes a technique through which a heater unit disposed in a high-pressure annealing device is able to be attached to or detached from the high-pressure annealing device through upward movement or downward movement of the heater unit from or toward the lower portion of an outer chamber in a state in which the heater unit is supported by a jig device.

Hereinafter, the present disclosure will be described with reference to the embodiments.

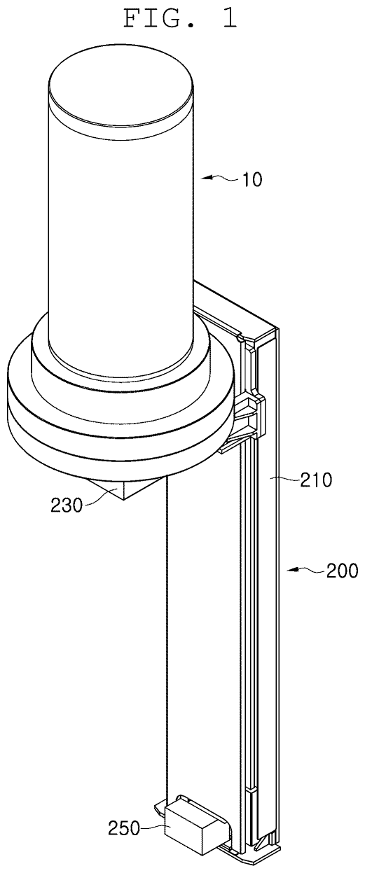

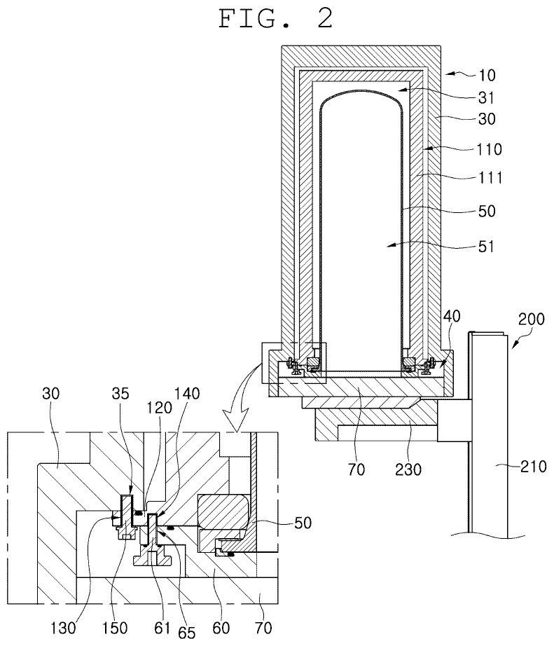

FIG. 1 is a perspective view of a high-pressure annealing device to which a system for attachment and detachment of a heater unit according to one embodiment the present disclosure is applied, and FIG. 2 is a cross-sectional view of the high-pressure annealing device to which the system for attachment and detachment of the heater unit according to one embodiment the present disclosure is applied.

A high-pressure annealing device 10 according to the present disclosure may have a dual chamber structure including an inner chamber 50 and an outer chamber 30.

The inner chamber 50 may perform an annealing process in a high-pressure environment. As an example, the inner chamber 50 is formed of a non-metallic material and is preferably formed of quartz. The material of the inner chamber 50 may be appropriately changed depending on circumstances.

The inner chamber 50 may be formed as an integrated chamber. Specifically, a lower portion of the inner chamber 50 is open, and the upper portion and the opposite side surface portions thereof are not open and are connected to each other. The inner chamber 50 may provide an inner space 51 in which a heat treatment process is performed on an object to be processed. A door 70 may be selectively attached to the open lower portion of the inner chamber 50, and the inner space 51 of the inner chamber 50 may be sealed by attachment of the door 70.

The object to be processed may be positioned in the inner space 51 of the inner chamber 50. For example, the object to be processed may be a wafer. Here, the wafers may be loaded in multiple layers on a wafer boat (not shown) and may be positioned in the inner space 51 of the inner chamber 50.

A first gas may be supplied to the inner space 51 of the inner chamber 50, and a heat treatment process gas may be supplied as the first gas. As an example, the first gas may be selected from various heat treatment gases such as hydrogen, deuterium, ammonia, oxygen, chlorine, and nitrogen.

When the first gas is supplied to the inner chamber 50, the inner space 51 of the inner chamber 50 is filled with the first gas. Accordingly, the inner space 51 of the inner chamber 50 may be increased to a first pressure. Here, the first pressure is a pressure higher than the atmospheric pressure and is selectively adjusted within a range of several atmospheres (atm) to hundreds of atmospheres (atm).

The outer chamber 30 may be provided to surround the inner chamber 50 in a state of being spaced apart from the inner chamber 50 by a predetermined distance.

The outer chamber 30 may be formed of a metallic material, and the material of the outer chamber 30 may be appropriately changed depending on circumstances. The outer chamber 30 may be formed as an integrated chamber. Specifically, a lower portion of the outer chamber 30 is open, and the upper portion and the opposite side surface portions thereof are not open and are connected to each other. For example, the outer chamber 30 may be formed as an integrated dome or cup having an upper surface and side walls that are formed to be integrated as one shape.

The outer chamber 30 may provide an outer space 31 for accommodation of the inner chamber 50. More specifically, the outer space 31 may be a space excluding an area occupied by the inner chamber 50 from the inner space provided by the outer chamber 30.

The outer chamber 30 may protect the inner chamber 50 by maintaining the outer space 31 at a pressure corresponding to the high pressure of the inner chamber 50. To this end, a second gas is supplied to the outer space 31 of the outer chamber 30, and a protective gas may be supplied as the second gas. As an example, the second gas may be selected from various inert gases such as nitrogen.

When the second gas is supplied to the outer chamber 30, the outer space 31 of the outer chamber 30 is filled with the second gas. Accordingly, the outer space 31 of the outer chamber 30 may be increased to a second pressure. Here, the second pressure may be adjusted to maintain a stable pressure range set in comparison with the first pressure. For example, the second pressure may be adjusted to be the same as the first pressure or to be slightly higher or lower than the first pressure. As an example, the stable pressure range may be set in consideration of a material strength of the inner chamber 50 and a heat treatment process profile. Preferably, the second pressure range is set in consideration of a pressure change between the inner chamber 50 and the outer chamber 30, which the inner chamber may withstand without damage thereof, and a temperature change of the inner chamber 50.

A heater unit 110 may be disposed between the inner chamber 50 and the outer chamber 30. More specifically, the heater unit 110 may be disposed outside the inner chamber 50 and may be disposed in the outer space 31 of the outer chamber 30.

The heater unit 110 may increase the temperature of the inner space 51 of the inner chamber 50.

The heater unit 110 may include a heating member (not shown) for generation of heat, an insulating member (not shown) for prevention of heat loss, and a heater body 111 mounted between the heating member and the insulating member and configured to support the same. As an example, the heater body 111 may be formed to surround at least a part of the inner chamber 50 with a material that is not deformed by heat, and a heating coil may be mounted on the heater body 111 as a heating member. As an example, the insulating member may be provided on the heater body 111 in such a manner that, in a state in which one side of the heating coil is exposed toward the inner chamber 50, remaining portions of the heating coil excluding the above-mentioned one side of the heating coil are surrounded by the insulating member. A structure in which a heating coil serving as a heating member is applied to the heater unit 110 is described as one embodiment. In addition to the heating coil, various structures capable of generating heat may be applied to the heater unit 110.

The heater unit 110 may be provided with a heater mounting portion, and the heater mounting portion may be mounted on the outer chamber 30 through a heater fastening means.

As an example, the heater mounting portion may include a heater flange 120 formed to protrude outwards from the lower end of the heater body 111 and to extend to contact a part of the outer chamber 30, and the heater fastening means may include a heater fastener 150 configured to fasten the heater flange 120 to a part of the outer chamber 30.

As an example, a heater unit fastening hole 35 for mounting of the heater unit 110 may be provided in the lower end of the outer chamber 30, and a heater fastening through-hole 130 may be provided in the heater flange 120 corresponding to the heater unit fastening hole 35 in the outer chamber 30.

Preferably, a plurality of heater unit fastening holes 35 may be provided in the lower end of the outer chamber 30 along the circumference of the outer chamber in a state of being spaced apart from each other, and a plurality of heater fastening through-holes 130 may be provided in the heater flange 120 along the circumference of the heater flange in a state of being spaced apart from each other.

In a state in which the lower end of the outer chamber 30 and the upper surface of the heater flange 120 of the heater unit 110 are in contact with each other, the heater fastener 150 may be fastened into the heater unit fastening hole 35 in the outer chamber 30 by passing through the heater fastening through-hole 130 in the heater flange 120. The heater unit 110 may be fixedly mounted on the outer chamber 30 through the heater fastener 150.

Although the present embodiment shows a case in which a fastener such as a rivet or a bolt is applied as the heater fastening means, this case is only one example, and various fastening methods such as a clamp may be applied as the heater fastening means.

A sealing member is mounted between the lower end of the outer chamber 30 and the heater flange 120 of the heater unit 110 to prevent leakage of the second gas supplied to the outer space 31 of the outer chamber 30.

The inner chamber 50 may be mounted on an inner chamber support plate 60. As an example, the inner chamber support plate 60 may have a central portion formed to be open corresponding to a cross-sectional area of the open lower end of the inner chamber 50.

As an example, a support plate fastening hole 140 may be provided in the lower surface of the heater flange 120 of the heater unit 110, and a support plate fastening through-hole 65 may be provided in the inner chamber support plate 60 corresponding to the support plate fastening hole 140.

Preferably, a plurality of support plate fastening holes 140 may be provided in the lower surface of the heater flange 120 along the circumference of the heater flange in a state of being spaced apart from each other, and a plurality of support plate fastening through-holes 65 may be provided in the inner chamber support plate 60 along the circumference of the inner chamber support plate in a state of being spaced apart from each other.

In a state in which the lower surface of the heater flange 120 and the upper surface of the inner chamber support plate 60 are in contact with each other, a support plate fastener 61 may be fastened into the support plate fastening hole 140 in the heater flange 120 by passing through the support plate fastening through-hole 65 in the inner chamber support plate 60. The inner chamber support plate 60 may be fixedly mounted on the heater flange 120 of the heater unit 110 through the support plate fastener 61.

A sealing member may be mounted between the inner chamber support plate 60 and the heater flange 120 of the heater unit 110, and a sealing member may be mounted between the inner chamber 50 and the inner chamber support plate 60. Through such a structural configuration, leakage of the second gas supplied to the inner space 51 of the inner chamber 50 may be prevented. In addition, a buffer member may be mounted between the heater unit 110 and the inner chamber 50 to prevent damage to the inner chamber 50.

The coupling structure of the inner chamber 50, the heater unit 110, and the outer chamber 30 described above may be appropriately modified depending on circumference. As an example, the inner chamber support plate 60 supporting the inner chamber 50 may be coupled to the outer chamber 30.

An object to be processed may be mounted on the door 70. The door 70 may be inserted into a door insertion space 40 provided in the lower end of the outer chamber 30 while being moved upwards, thereby positioning the object to be processed in the inner space 51 of the inner chamber 50 and sealing the inner space 51 of the inner chamber 50.

An upward/downward movement device 200 may move the door 70 upwards or downwards.

As an example, the upward/downward movement device 200 may include a support frame 210, a door support arm 230, an upward/downward movement actuator 250, and the like.

The support frame 210 may be vertically disposed and may support vertical movement of the door support arm 230 while guiding the same.

The door support arm 230 may be moved upwards or downwards along the support frame 210 while one side thereof is supported by the support frame 210. The door 70 may be mounted on the door support arm 230.

The upward/downward movement actuator 250 may provide power for upward movement or downward movement of the door support arm 230. As an example, the support frame 210 may be provided with a belt, a chain, and the like, and the door support arm 230 may be coupled to the belt, the chain, and the like. In this case, the upward/downward movement actuator 250 may rotate the belt, the chain, and the like to move the door support arm 230 upwards or downwards. Alternatively, the support frame 210 may be provided with a rail, and one side of the door support arm 230 may be coupled to the rail. In this case, the upward/downward movement actuator 250 may provide power to move the door support arm 230 upwards or downwards along the rail. In addition thereto, the upward/downward movement device 200 may include various configurations for upward movement and downward movement of the door support arm 230.

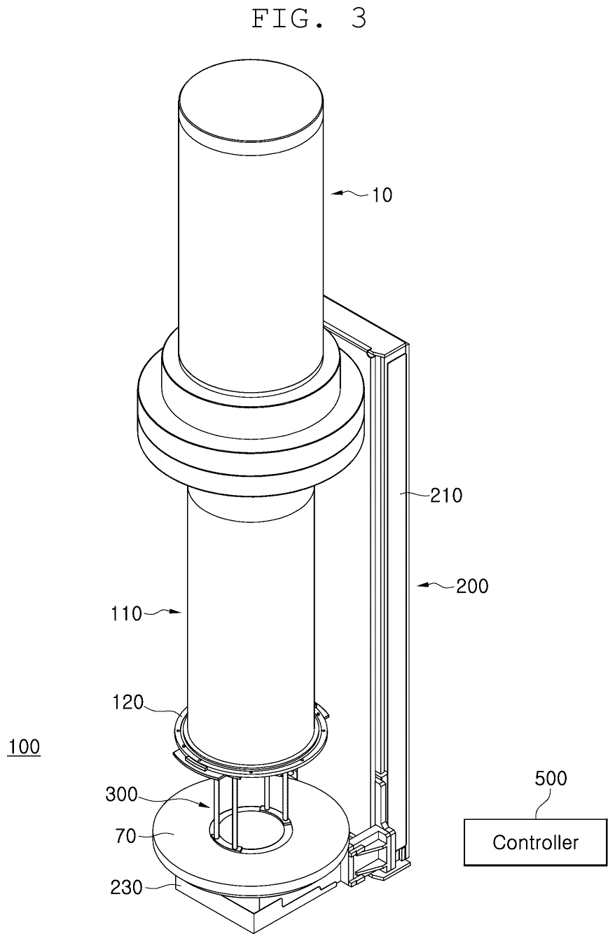

FIG. 3 is a view showing the system for attachment and detachment of the heater unit according to one embodiment the present disclosure.

In the present embodiment, a system 100 for attachment and detachment of the heater unit is described as being applied to the high-pressure annealing device 10 shown in FIGS. 1 and 2, but the present disclosure is not limited thereto. The system 100 for attachment and detachment of the heater unit may be applied to various high-pressure annealing devices 10 in which the lower portion of the outer chamber 30 is open.

For example, in the embodiments of FIGS. 1 and 2, although the outer chamber 30 is described as an integrated chamber having an open lower portion and upper and side surface portions that are not open and are connected to each other, the system 100 for attachment and detachment of the heater unit may also be applied to a case in which the lower portion of the outer chamber is open and the upper portion thereof is selectively open.

The system 100 for attachment and detachment of the heater unit may attach the heater unit 110 to the high-pressure annealing device 10 or detach the heater unit 110 from the high-pressure annealing device 10.

The system 100 for attachment and detachment of the heater unit may include a jig device 300, the upward/downward movement device 200, a controller 500, and the like.

The jig device 300 may be mounted on the upward/downward movement device 200 and may support the heater unit 110 while being moved upwards or downwards by the upward/downward movement device 200. As an example, the jig device 300 may detect the mounting state of the heater unit 110 while guiding mounting of the heater unit 110.

The controller 500 may control the upward/downward movement device 200 to move the jig device 300 upwards or downwards. As an example, the controller 500 may receive a mounting detection signal of the heater unit 110 from the jig device 300 and may determine the mounting state of the heater unit 110 on the jig device 300.

Through such a structural configuration, the system 100 for attachment and detachment of the heater unit may attach or detach the heater unit 110 to or from the high-pressure annealing device 10 by moving the jig device 300 upwards or downwards through the upward/downward movement device 200 in a state in which the heater unit 110 is supported by the jig device 300.

In the present embodiment, the jig device 300 is described as being mounted on the upper surface of the door 70 in a state in which the door 70 is mounted on the door support arm 230 of the upward/downward movement device 200, but this structural configuration is an example. The jig device 300 may be mounted on the door support arm 230 from which the door 70 is removed.

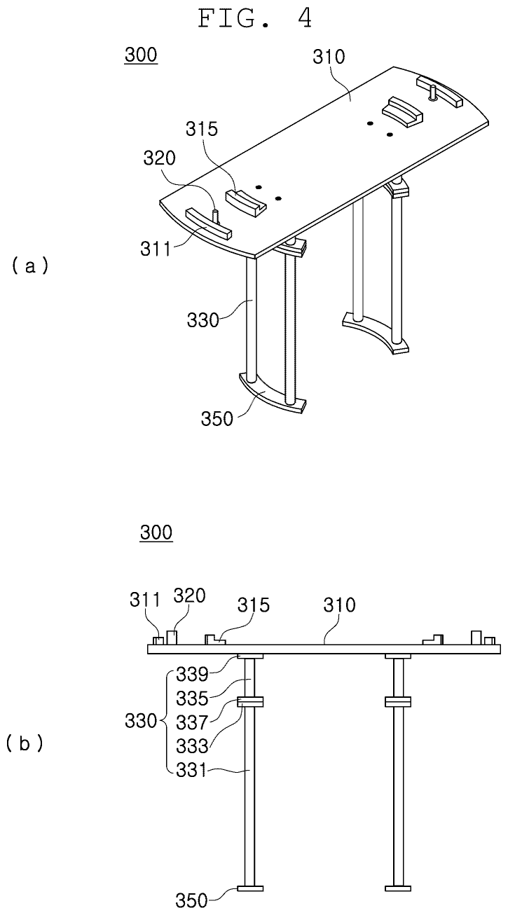

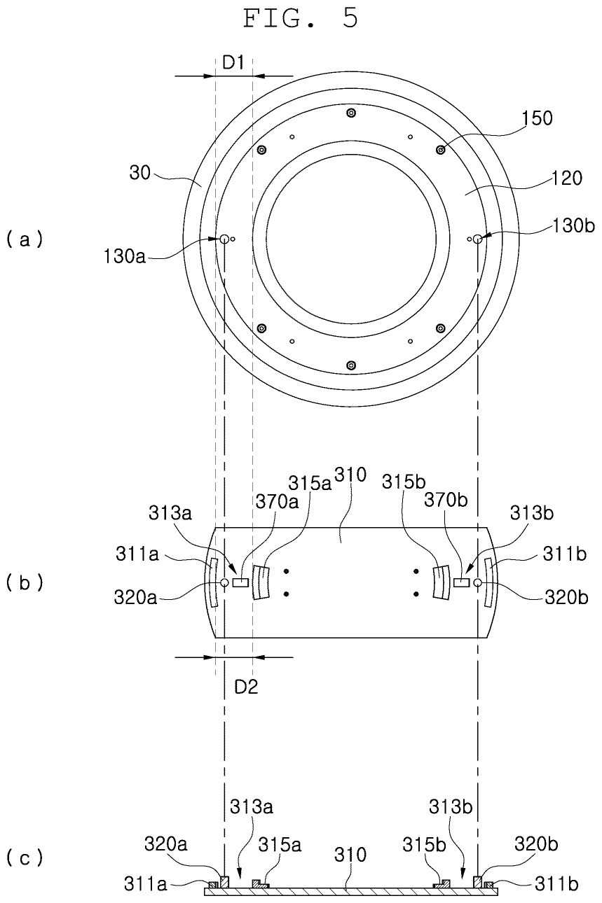

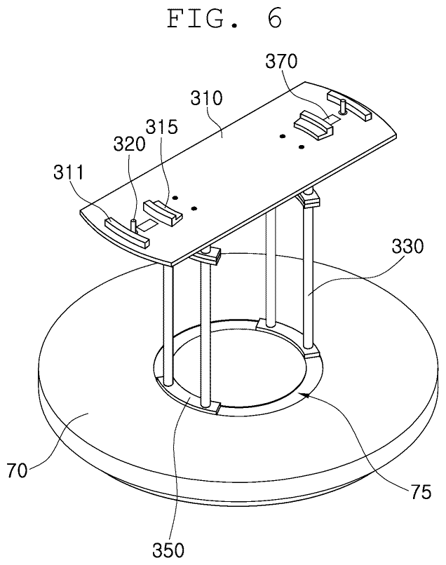

FIG. 4 is a view showing the jig device of the system for attachment and detachment of the heater unit according to one embodiment of the present disclosure, FIG. 5 is a view showing the size of a heater support plate of the jig device and the size of the heater unit according to one embodiment of the present disclosure, and FIG. 6 is a view showing one embodiment in which the jig device according to the present disclosure is mounted on the door.

The jig device 300 may include a heater support plate 310, a jig leg 330, a jig support plate 350, and the like.

The lower surface of the heater unit 110 may be mounted on the upper surface of the heater support plate 310. As an example, the heater flange 120 of the heater unit 110 may be mounted on the upper surface of the heater support plate 310.

Mounting guide bars 311 and 315 may be provided on the upper surface of the heater support plate 310.

The mounting guide bars 311 and 315 may prevent detachment of the heater unit 110 by closely contacting the lower side surface of the heater unit 110 while guiding the lower surface of the heater unit 110 to be properly mounted on the heater support plate 310.

The mounting guide bars 311 and 315 may include a first mounting guide bar 311 and a second mounting guide bar 315.

The first mounting guide bar 311 and the second mounting guide bar 315 are disposed spaced apart from each other, and the lower end portion of the heater unit 110 may be inserted into and mounted in a space formed between the first mounting guide bar 311 and the second mounting guide bar 315. A separation distance between the first mounting guide bar 311 and the second mounting guide bar 315 may be adjusted corresponding to the size of the lower end portion of the heater unit 110.

The mounting guide bars 311 and 315 may have a predetermined height so as to stably support the heater unit 110 mounted on the heater support plate 310.

As an example, a plurality of mounting guide bars 311 and 315 may be provided on the upper surface of the heater support plate 310.

Referring to FIG. 5, FIG. 5(a) is a view showing the lower portion of the high-pressure annealing device, FIG. 5(b) is a view showing the upper portion of the heater support plate, and FIG. 5(c) is a view showing a cross section of the heater support plate.

The longitudinal length of the heater support plate 310 may be larger than the diameter of the heater flange 120 of the heater unit 110 and may be smaller than the diameter of the door insertion space 40 formed in the lower end in the outer chamber 30.

As an example, as a plate shape of the heater support plate 310, each of the longitudinally opposite ends of the support plate 310 may be formed to have an arc shape corresponding to the cross-sectional shape of the door insertion space 40.

Preferably, the width of the heater support plate 310 may be adjusted so as not to block, among a plurality of the heater fastening through-holes 130 provided in the heater flange 120 of the heater unit 110, the heater fastening through-holes 130 other than the heater fastening through-holes functioning as alignment holes 130a and 130b.

The mounting guide bars 311 and 315 may be provided on the longitudinally opposite sides of the upper surface of the heater support plate 310, respectively.

First mounting guide bars 311a and 311b and second mounting guide bars 315a and 315b may be provided on the longitudinally opposite sides of the heater support plate 310, respectively. Each of the first mounting guide bars 311a and 311b and a corresponding one of the second mounting guide bars 315a and 315b may be positioned apart from each other by a distance D2 corresponding to a lower width D1 of the heater flange 120. That is, the distance D2 between each of the first mounting guide bars 311a and 311b and a corresponding one of the second mounting guide bars 315a and 315b may be equal to or slightly larger than the lower width D1 of the heater flange 120.

A space between each of the first mounting guide bars 311a and 311b and a corresponding one of the second mounting guide bars 315a and 315b may be mounting spaces 313a and 313b in which the heater flange 120 of the heater unit 110 is mounted.

An alignment means may be provided on the upper surface of the heater support plate 310. The alignment means may include an alignment pin 320. As an example, alignment pins 320a and 320b may be respectively provided in a space formed between the first mounting guide bar 311a and the second mounting guide bar 315a and a space formed between the first mounting guide bar 311b and the second mounting guide 315b. Accordingly, the alignment pins 320a and 320b may be respectively provided on the longitudinally opposite sides of the heater support plate 310.

When the heater unit 110 is mounted on the heater support plate 310, the alignment pins 320a and 320b are respectively inserted and fastened into the alignment holes 130a and 130b provided in the heater flange 120 of the heater unit 110, thereby making it possible to guide the precise mounting position of the heater unit 110 on the heater support plate 310.

As an example, the heater fastening through-hole 130 provided in the heater flange 120 may function as an alignment hole. Alternatively, a separate alignment hole may be provided in the heater flange 120 in addition to the heater fastening through-hole 130.

The alignment means may include a light emitter. As an example, a light emitter (not shown) may be provided in the alignment pin 320. The light emitter may emit light upwards in the vertical direction. Preferably, the light emitter emits light having a color so that a light path is visually recognized.

The mounting position of the jig device 300 may be aligned in such a manner that, in a state in which light emitted from the light emitter is aligned with each of the alignment holes 130a and 130b provided in the heater flange 120 of the heater unit 110, the heater unit 110 is mounted on the jig device 300.

A heater unit detection sensor 370 may be provided on the heater support plate 310. The heater unit detection sensor 370 may detect the mounting state of the heater unit 110 on the heater support plate 310.

As an example, heater unit detection sensors 370a and 370b may be respectively provided in a space formed between the first mounting guide bar 311a and the second mounting guide bar 315a and a space formed between the first mounting guide bar 311b and the second mounting guide bar 315b. Accordingly, the heater unit detection sensors 370a and 370b may be respectively provided on the longitudinally opposite sides of the heater support plate 310.

As an example, each of the heater unit detection sensors 370a and 370b may include a pressure sensor configured to measure a degree of contact pressure and an optical sensor configured to emit light and receive reflected light so as to detect the position of the heater flange 120 of the heater unit 110 mounted on the heater support plate 310. The plurality of heater unit detection sensors 370a and 370b may detect a distance between the upper surface of the heater support plate 310 and the heater flange 120 of the heater unit 110 or a degree of pressurization of the heater flange 120 relative to the heater support plate 310.

The controller 500 may determine, based on detection signals from the plurality of heater unit detection sensors 370a and 370b, the mounting state of the heater unit 110 on the heater support plate 310. For example, when the separation distances or the degrees of pressurization respectively detected from the heater unit detection sensors 370a and 370b are the same or are similar to each other within an error range as a result of comparison between the plurality of detection signals, the controller 500 may determine that the heater unit 110 is normally mounted on the heater support plate 310. Conversely, when the separation distances or the degrees of pressurization respectively detected from the heater unit detection sensors 370a and 370b are different and a difference therebetween exceeds the error range as a result of comparison between the plurality of detection signals, the controller 500 may determine that the heater unit 110 is abnormally mounted on the heater support plate 310.

Furthermore, the controller 500 may provide information on the mounting state of the heater unit 110.

The jig leg 330 may be connected to the lower surface of the heater support plate 310 to support the heater support plate 310.

The jig leg 330 may be provided in plural so as to distribute the load of the heater support plate 310 and to stably support the heater support plate 310.

As an example, two jig legs 330 may be respectively provided on one side and the other side of the heater support plate 310 in the longitudinal direction. Of course, the number and position of the jig legs 330 may be changed depending on circumstances.

The height of the jig leg 330 may be adjusted. As an example, the jig leg 330 may include a first jig leg 331 and a second jig leg 335. The height of the jig leg 330 may be adjusted according to the selective combination of the first jig leg 331 and the second jig leg 335. For example, the height of the jig leg 330 may be adjusted depending the required work space size.

The upper side of the first jig leg 331 may be connected to a first upper fastening bar 333, and the lower side of the first jig leg 331 may be connected to a first lower fastening bar 350.

For example, a plurality of first jig legs 331 may be connected to the first upper fastening bar 333 and the first lower fastening bar 350 in a state of being spaced apart from each other.

The upper side of the second jig leg 335 may be connected to a second upper fastening bar 339, and the lower side of the second jig leg 335 may be connected to a second lower fastening bar 337.

As an example, a plurality of second jig legs 335 may be connected to the second upper fastening bar 339 and the second lower fastening bar 337 in a state of being spaced apart from each other.

When the first jig leg 331 and the second jig leg 335 are connected to each other, the first upper fastening bar 333 and the second lower fastening bar 337 may be connected to each other. The second upper fastening bar 339 of the second jig leg 335 may be connected to the lower surface of the heater support plate 310. The first lower fastening bar 350 of the first jig leg 331 may function as the jig support plate 350. Depending on circumstances, a separate jig support plate may be provided, and the first lower fastening bar 350 of the first jig leg 331 may be connected to the jig support plate.

When only the first jig leg 331 is provided without the second jig leg 335, the first upper fastening bar 333 may be connected to the lower surface of the heater support plate 310.

As in the embodiment in FIG. 6, the jig device 300 may be mounted on the door 70. The jig support plate 350 of the jig device 300 may be mounted on the upper surface of the door 70.

As an example, a jig mounting groove 75 is provided in the upper surface of the door 70, and the jig support plate 350 may be inserted into the jig mounting groove 75.

As another example, a jig mounting groove (not shown) may be provided in the door support arm 230, and the jig support plate 350 of the jig device 300 may be inserted into the jig mounting groove in the door support arm 230 from which the door 70 is removed.

In the present embodiment, two jig support plates 350 are formed corresponding to the jig legs 330 connected to the opposite side surfaces of the heater support plate 310, but the number and shape of the jig support plate 350 may be adjusted depending on the number and position of the jig legs 330.

The jig device 300 may be mounted on the upper surface of the door 70 or may be mounted on the door support arm 230 from which the door 70 is removed, and the jig device 300 may be moved upwards or downwards by the upward/downward movement device 200.

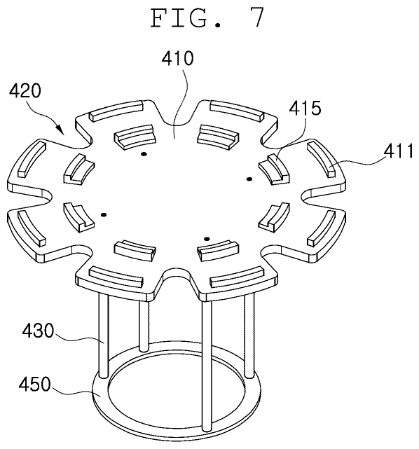

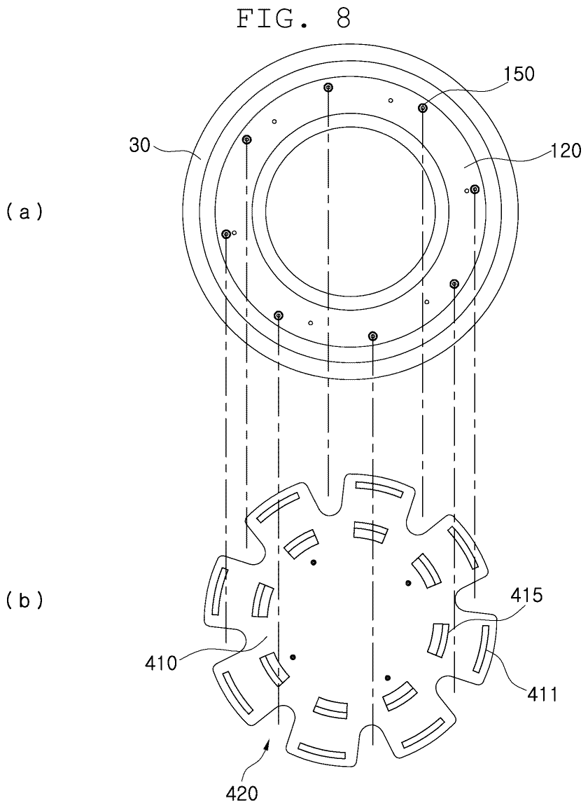

The jig device according to the present disclosure may be modified in various ways. As a modification of the jig device, FIG. 7 is a view showing another embodiment of the jig device of the system for attachment and detachment of the heater unit according to the present disclosure, and FIG. 8 is a view showing the size of the heater support plate of the jig device and the size of the heater unit according to another embodiment of the present disclosure.

In describing the embodiments in FIGS. 7 and 8, a description of a portion overlapping the description of the embodiment of the above-described jig device will be omitted or briefly described.

The jig device 400 may include a heater support plate 410, a jig leg 430, and a jig support plate 450.

The heater support plate 410 may be formed to have a shape corresponding to the shape of the lower surface of the heater unit 110.

As an example, the heater support plate 410 may be formed to have a disc shape. In this case, the diameter of the heater support plate 410 may be larger than the diameter of the heater flange 120 of the heater unit 110 and may be smaller than the diameter of the door insertion space 40 provided in the lower end of the outer chamber 30.

The heater support plate 410 may have open fastening work spaces 420 in which portions corresponding to a plurality of heater fastening through-holes 130 provided in the heater flange 120 of the heater unit 110 are recessed inwards and are open. When the heater unit 110 is mounted on the jig device 400 through the fastening work space 420, the heater fastener 150 fastened into the heater fastening through-hole 130 may be exposed without being covered by the heater support plate 410.

The fastening work space 420 may be formed to correspond to the shape of the heater fastener 150.

Preferably, the fastening work space 420 is formed to facilitate fastening and separating operations of the heater fastener 150.

A plurality of mounting guide bars 411 and 415 may be provided on the upper surface of the heater support plate 410 along the circumference of the heater support plate 410 in a state of being spaced apart from each other.

The mounting guide bars 411 and 415 may include a first mounting guide bar 411 and a second mounting guide bar 415.

The first mounting guide bar 411 and the second mounting guide bar 415 are spaced apart from each other, and the lower end portion of the heater unit 110 may be inserted into and mounted in a space formed between the first mounting guide bar 411 and the second mounting guide bar 415. A separation distance between the first mounting guide bar 411 and the second mounting guide bar 415 may be adjusted corresponding to the size of the lower end portion of the heater unit 110.

The jig leg 430 may connect the heater support plate 410 to the jig support plate 450. One side of the jig leg 430 may be connected to the lower surface of the heater support plate 410, and the other side thereof may be connected to the upper surface of the jig support plate 450.

A plurality of jig legs 430 may be provided in a state of being spaced apart from each other so as to distribute the load of the heater support plate 410 and support the heater support plate 410.

The jig support plate 450 may be mounted on the door 70 or the door support arm 230 of the upward/downward movement device 200.

As an example, the jig support plate 450 may be formed to have a circular ring shape in which all the other sides of the plurality of jig legs 430 are connected to each other. The jig support plate 450 may be inserted into the jig mounting groove 75 provided in the upper surface of the door 70 or the jig mounting groove provided in the door support arm 230.

In this manner, the jig device may be changed into various forms capable of stably supporting the heater unit while evenly distributing the load of the heater unit.

The operation of the system for attachment and detachment of the heater unit according to the present disclosure will be described with reference to an embodiment.

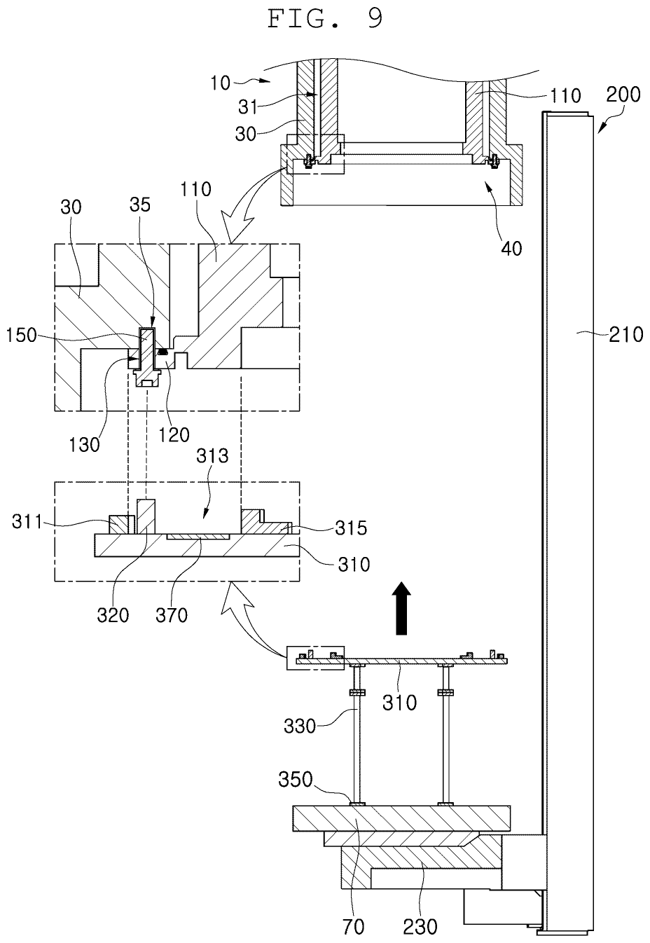

FIGS. 9 to 11 are views each showing the embodiment of the operation of detaching the heater unit from the high-pressure annealing device through the system for attachment and detachment of the heater unit according to the present disclosure.

The embodiment in FIGS. 9 to 11 is a case in which the jig device shown in FIGS. 4 to 6 is applied, and as another embodiment, the operation of the jig device shown in FIGS. 7 and 8 may also be inferred through the present embodiment, so a description thereof will be omitted.

The present embodiment assumes a state in which the inner chamber 50 is removed from the high-pressure annealing device 10.

FIG. 9 shows an example in which the jig device 300 is mounted on the door 70, and the jig device 300 is moved upwards through the upward/downward movement device 200.

The jig device 300 may be mounted on the door 70. As described above, the jig support plate 350 may be inserted into the jig mounting groove 75 in the door 70 for mounting of the jig device 300.

The mounting position of the jig device 300 on the door 70 may be adjusted by aligning the alignment pin 320 of the jig device 300 with the heater fastener 150 fastened into the heater fastening through-hole 130 functioning as an alignment hole.

As an example, the mounting position of the jig device 300 may be adjusted by aligning light emitted from a light emitter (not shown) of a jig alignment means provided on the alignment pin 320 with the heater fastening through-hole 130 functioning as an alignment hole.

As described above, in a state in which the position of the jig device 300 on the door 70 is adjusted, the heater fastener 150 fastened into the heater fastening through-hole 130 functioning as an alignment hole may be removed. In this case, the heater fastener 150 fastened into another heater fastening through-hole 130 other than the heater fastener 150 fastened into the heater fastening through-hole 130 functioning as an alignment hole maintains the fastening state thereof.

Then, when the door 70 is moved upwards through the upward/downward movement device 200, the jig device 300 mounted on the door 70 may be moved upwards toward the door insertion space 40 provided in the lower end of the outer chamber 30.

As an example, while the jig device 300 is moved upwards, the controller 500 may receive detection signals from a plurality of heater unit detection sensors 370 and may determine stability of the operating state based on the signals.

As an example, the plurality of heater unit detection sensors 370 may emit light toward the lower surface of the heater unit 110 and may receive reflected light, and the controller 500 may determine, based on comparison between the detection signals from the respective heater unit detection sensors 370, whether the jig device 300 is in a state of being normally moved upwards toward the heater unit 110.

For example, when detected separation distances are the same or are similar to each other within an error range as a result of comparison between the plurality of detection signals, the controller 500 may determine that the jig device 300 is in a state of being normally moved upwards toward the heater unit 110.

When the detected separation distances are different and a difference therebetween exceeds the error range as a result of comparison between the plurality of detection signals, the controller 500 may determine that the jig device 300 is in a state of being abnormally moved upwards toward the heater unit 110.

Furthermore, the controller 500 may provide information on the operating state.

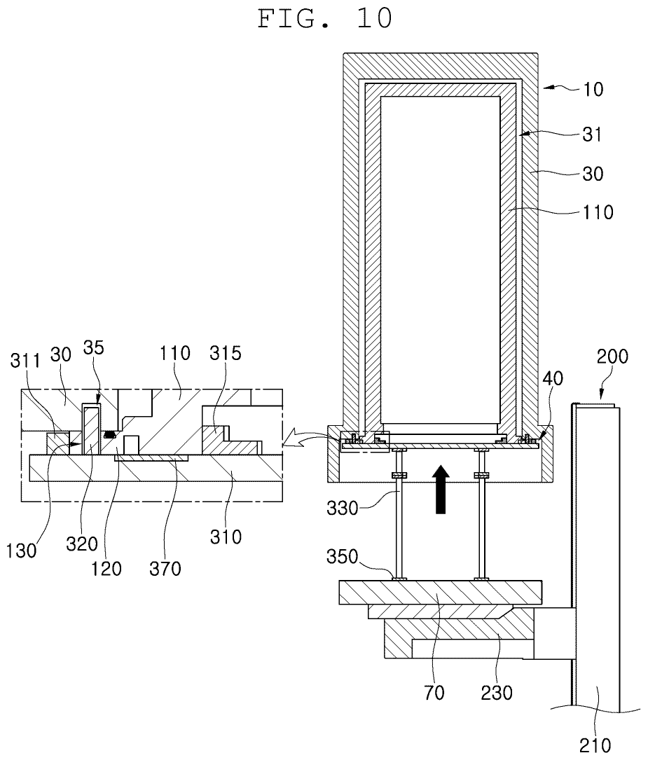

FIG. 10 is a view showing an example in which the jig device 300 is moved upwards and the heater unit 110 is mounted on the heater support plate 310 of the jig device 300.

The jig device 300 is moved upwards through the upward/downward movement device 200, and the heater support plate 310 of the jig device 300 may be inserted into the door insertion space 40 provided in the lower end of the outer chamber 30. The heater flange 120 of the heater unit 110 may be mounted on the upper surface of the heater support plate 310.

The heater flange 120 of the heater unit 110 may be mounted in the space formed between the first mounting guide bar 311 and the second mounting guide bar 315 provided on the upper surface of the heater support plate 310. The heater flange 120 of the heater unit 110 is guided by the first mounting guide bar 311 and the second mounting guide bar 315 so as to allow the upper surface of the heater support plate 310 to contact the lower surface of the heater unit 110.

Accuracy of the mounting position of the heater unit 110 on the jig device 300 may be ensured when the alignment pin 320 of the jig device 300 is inserted and fastened into the alignment hole 130 provided in the heater flange 120 of the heater unit 110.

As an example, the mounting state of the heater unit 110 on the heater support plate 310 is detected through a plurality of heater unit detection sensors 370 provided on the jig device 300, and the controller 500 may determine the current mounting state based on the detected mounting state.

For example, when detected separation distances are the same or are similar to each other within an error range or detected degrees of pressurization are the same or are similar to each other within an error range as a result of comparison between a plurality of detection signals, the controller 500 may determine that the heater unit 110 is in a state of being normally mounted on the jig device 300. When the detected separation distances or the detected degrees of pressurization are different and a difference therebetween exceeds the error range as a result of comparison between the plurality of detection signals, the controller 500 may determine that the heater unit 110 is in a state of being abnormally mounted on the jig device 300.

Furthermore, the controller 500 may provide information on the mounting state of the heater unit 110.

As shown in FIG. 10, in a state in which the heater unit 110 is mounted and supported on the jig device 300, the remaining heater fasteners 150 respectively fastened into the heater fastening through-holes 130 may be removed.

In particular, as described above, the width of the heater support plate 310 is adjusted so as not to block, among a plurality of heater fastening through-holes 130 provided in the heater flange 120 of the heater unit 110, any heater fastening through-holes other than those functioning as the alignment holes 130a and 130b, and the heater support plate 310 is sufficiently spaced apart from the door 70 through the jig leg 330. Accordingly, the heater fasteners 150 respectively fastened into the heater fastening through-holes 130 in the heater unit 110 may be easily removed.

When all of the heater fasteners 150 that are fastened so as to allow the heater unit 110 to be supported by the outer chamber 30 are removed, the heater unit 110 is entirely mounted on and supported by the jig device 300.

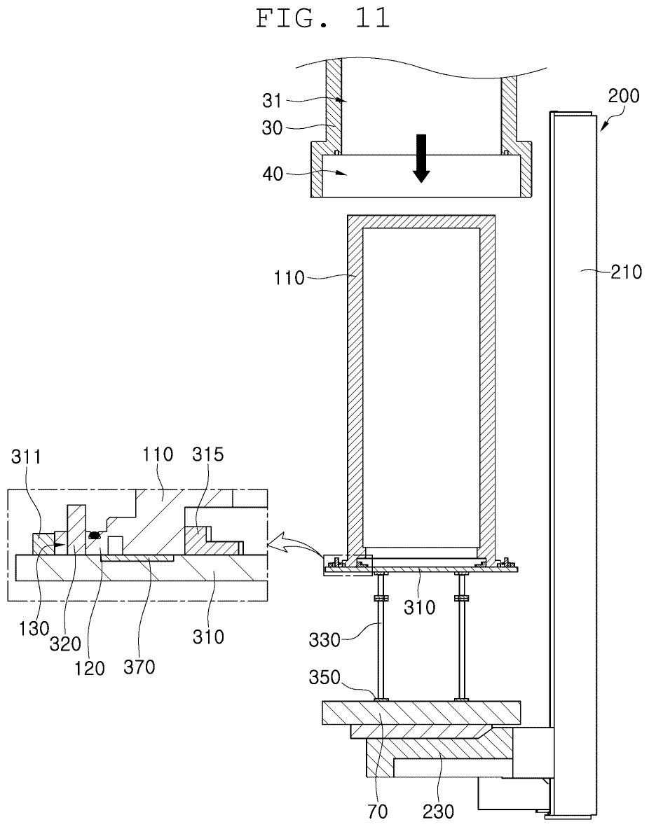

FIG. 11 is a view showing an example in which the jig device 300 is moved downwards such that the heater unit 110 mounted on the jig device 300 is detached from the high-pressure annealing device 10.

When the door 70 is moved downwards through the upward/downward movement device 200 in a state in which the heater unit 110 is entirely supported by the jig device 300, the heater unit 110 mounted on the jig device 300 may be moved downwards so as to be withdrawn from the door insertion space 40 provided in the lower end of the outer chamber 30.

For example, when the jig device 300 is moved downwards, the controller 500 may receive detection signals from the plurality of heater unit detection sensors 370 and may determine stability of the operating state based on the detection signals.

For example, the plurality of heater unit detection sensors 370 respectively detect the degrees of pressurization by the heater unit 110, and the controller 500 may determine, based on comparison between the detection signals from the respective heater unit detection sensors 370, whether the jig device 300 on which the heater unit 110 is mounted is in a state of being normally moved downward.

For example, when the detected degrees of pressurization are the same or are similar to each other within an error range as a result of comparison between the plurality of detection signals, the controller 500 may determine that the heater unit 110 is moved downwards in a state of being normally mounted on the jig device 300.

When the detected degrees of pressurization are different and a difference therebetween exceeds the error range as a result of comparison between the plurality of detection signals, the controller 500 may determine that the heater unit 110 is moved downwards in a state of being abnormally mounted on the jig device 300.

Furthermore, the controller 500 may provide information on the operating state.

The upward/downward movement device 200 may move the jig device 300 on which the heater unit 110 is mounted downwards until the entire heater unit 110 is completely withdrawn from the lower portion of the outer chamber 30.

According to the present disclosure, the heater unit may be attached to or detached from the high-pressure annealing device through upward movement or downward movement of the heater unit from or toward the lower portion of the outer chamber in a state in which the heater unit disposed in the high-pressure annealing device is supported by the jig device, thereby significantly improving stability, speed, and ease of maintenance work of the high-pressure annealing device.

In particular, in the present disclosure, since the heater unit is withdrawn from the lower portion of the outer chamber using the upward/downward movement device configured to move the door upwards or downwards, a separate space for withdrawal of the heater unit is not required, thereby significantly reducing a work space for maintenance of the high-pressure annealing device.

Furthermore, in the present disclosure, since the heater unit is moved upwards or downwards in a state in which the jig device is mounted on the upward/downward movement device configured to move the door upwards or downwards, a separate crane device for upward or downward movement of the heater unit is not required.

As is apparent from the above description, according to the present disclosure, a heater unit may be attached to or detached from a high-pressure annealing device through upward movement or downward movement of the heater unit from or toward the lower portion of an outer chamber in a state in which the heater unit disposed in the high-pressure annealing device is supported by a jig device, thereby having an effect of significantly improving stability, speed, and ease of maintenance work of the high-pressure annealing device.

Particularly, in the present disclosure, since the heater unit is withdrawn from the lower portion of the outer chamber using an upward/downward movement device configured to move a door upwards or downwards, a separate space for withdrawal of the heater unit is not required, thereby having an effect of significantly reducing a work space for maintenance of the high-pressure annealing device.

Furthermore, in the present disclosure, since the heater unit is moved upwards or downwards in a state in which the jig device is mounted on the upward/downward movement device configured to move the door upwards or downwards, a separate crane device for upward or downward movement of the heater unit is not required.

The effects of the present disclosure are not limited to the above-mentioned effects, and other effects not mentioned herein will be clearly understood by those skilled in the art to which the present disclosure pertains from the detailed description of the embodiments.

Although the preferred embodiments of the present disclosure have been disclosed for illustrative purposes, those skilled in the art will appreciate that various modifications, additions, and substitutions are possible, without departing from the scope and spirit of the disclosure. Therefore, the embodiments described in the present disclosure are not intended to limit the technical idea of the present disclosure, and the technical idea of the present disclosure is not limited by the embodiments. The protection scope of the present disclosure should be interpreted by the following claims, and all technical ideas within the scope equivalent thereto should be construed as being included in the scope of the present disclosure.

What is claimed is:

1. A jig device configured to support attachment and detachment of a heater unit, the jig device comprising:
a heater support plate configured to support the heater unit by allowing the heater unit to be mounted on an upper surface thereof; and
a jig support plate supported in contact with a door of a high-pressure annealing device or a door support arm of an upward/downward movement device,
wherein the heater unit mounted on the upper surface of the heater support plate is moved upwards or downwards by the upward/downward movement device.

2. The jig device as claimed in claim 1, further comprising a plurality of mounting guide bars disposed to protrude upwards from the upper surface of the heater support plate and configured to guide mounting of the heater unit on the heater support plate, the mounting guide bars being configured to prevent separation of the heater unit by closely contacting and supporting a side surface of a lower end portion of the heater unit.

3. The jig device as claimed in claim 2, wherein the mounting guide bars comprise a first mounting guide bar and a second mounting guide bar, and
wherein a separation distance between the first mounting guide bar and the second mounting guide bar is adjusted so as to allow the lower end portion of the heater unit to be inserted into and mounted in a space between the first mounting guide bar and the second mounting guide bar.

4. The jig device as claimed in claim 1, wherein the heater support plate is formed to have a plate shape, and a longitudinal length of the heater support plate is larger than a diameter of a lower end surface of the heater unit and is smaller than a diameter of a door insertion space provided in a lower end of an outer chamber.

5. The jig device as claimed in claim 4, wherein a width of the heater support plate is adjusted so as not to cover but to open, among a plurality of heater fastening through-holes configured for a plurality of heater fasteners to be respectively fastened thereinto so as to fixedly mount the heater unit on the outer chamber, the heater fastening through-holes other than the heater fastening through-holes each functioning as an alignment hole.

6. The jig device as claimed in claim 1, wherein the heater support plate is formed to have a disc shape, and a diameter of the heater support plate is larger than a diameter of the heater unit and is smaller than a diameter of a door insertion space provided in a lower end of an outer chamber.

7. The jig device as claimed in claim 6, wherein the heater support plate has a plurality of fastening work spaces respectively formed in portions thereof corresponding to a plurality of heater fastening through-holes, the portions being formed to be recessed inwards and open, the heater fastening through-holes being configured for a plurality of heater fasteners to be respectively fastened thereinto, the heater fasteners being configured to fixedly mount the heater unit on the outer chamber.

8. The jig device as claimed in claim 1, further comprising an alignment pin formed to protrude upwards from the upper surface of the heater support plate and inserted into an alignment hole provided in the heater unit.

9. The jig device as claimed in claim 1, further comprising a plurality of heater unit detection sensors respectively disposed at a plurality of locations of the heater support plate in a state of being spaced apart from each other, each of the heater unit detection sensors being configured to measure a distance between the heater unit and the heater support plate or a degree of pressurization by the heater unit.

10. The jig device as claimed in claim 1, further comprising a plurality of jig legs connecting the heater support plate to the jig support plate,
wherein the jig legs are adjusted in height depending on a size of a required work space.

11. A system for attachment and detachment of a heater unit, the system comprising:
the jig device as claimed in claim 1 configured for the heater unit in a high-pressure annealing device to be mounted thereon; and
an upward/downward movement device configured to move the jig device upwards or downwards,
wherein the heater unit is attached to or detached from the high-pressure annealing device through upward movement or downward movement of the heater unit from or toward a lower portion of an outer chamber of the high-pressure annealing device in a state in which the heater unit is supported by the jig device.

12. The system as claimed in claim 11, wherein the upward/downward movement device moves a door of the high-pressure annealing device upwards or downwards.

13. The system as claimed in claim 12, wherein the upward/downward movement device comprises a door support arm configured for the door to be mounted thereon, the door support arm being moved upwards or downwards by the upward/downward movement device, and
wherein the jig device is mounted on the door support arm from which the door is removed.

14. The system as claimed in claim 11, wherein the jig device comprises a plurality of heater unit detection sensors respectively disposed at a plurality of locations of a heater support plate in a state of being spaced apart from each other, the heater support plate being configured for the heater unit to be mounted thereon, the heater unit detection sensors each being configured to measure a separation distance between the heater unit and the heater support plate or a degree of pressurization by the heater unit,
the system further comprising a controller configured to determine, based on detection signals from the plurality of heater unit detection sensors, an operating state of the jig device or a mounting state of the heater unit.

15. A high-pressure annealing device configured to attach or detach a heater unit thereto or therefrom, the high-pressure annealing device comprising:
an inner chamber having an inner space formed therein and configured for a heat treatment process on an object to be processed to be performed therein, the inner space being adjusted to a first pressure;
an outer chamber having an open lower portion and closed upper and side surface portions formed to be integrated with each other, the outer chamber having an outer space formed to be spaced apart from the inner chamber and configured to accommodate the inner chamber therein, the outer space being adjusted to a second pressure; and
a heater unit disposed between the inner chamber and the outer chamber, the heater unit comprising a heater mounting portion fastened to the outer chamber, the heater mounting portion being selectively fastened to the outer chamber through a heater fastening means such that the heater unit is selectively mounted on the outer chamber and is withdrawn from the open lower portion of the outer chamber.

16. The high-pressure annealing device as claimed in claim 15, wherein the heater mounting portion of the heater unit comprises a heater flange formed to protrude outwards from a lower end of a heater body, and
wherein a heater fastener of the heater fastening means penetrates an upper surface of the heater flange from a lower surface thereof and is fastened to the outer chamber in a state in which the upper surface of the heater flange is in contact with a part of the outer chamber, thereby enabling the heater unit to be selectively mounted on the outer chamber.
